(19) United States
(12) Patent Application Publication
(10) Pub. No.: US 2009/0277500 A1
(43) Pub. Date: Nov. 12, 2009

(54) TRANSPARENT SOLAR CELL MODULE

(75) Inventors: Te-Chi Wong, Chiayi County (TW); I-Min Chan, Taoyuan County (TW); Chao-Hsien Kuo, Hsinchu City (TW)

Correspondence Address: JIANQ CHYUN INTELLECTUAL PROPERTY OFFICE, 7 FLOOR-1, NO. 100, ROOSEVELT ROAD, SECTION 2, TAIPEI, 100, TW

(73) Assignee: INDUSTRIAL TECHNOLOGY RESEARCH INSTITUTE, Hsinchu (TW)

(21) Appl. No.: 12/110,366

(22) Filed: Apr. 28, 2008

(30) Foreign Application Priority Data
Dec. 31, 2007 (TW) 96151543

(51) Int. Cl. H01L 31/00

(52) U.S. Cl. 136/256

(57) ABSTRACT

A transparent solar cell module including a transparent solar cell and an optical transparent substrate is provided. The optical transparent substrate includes an optical filter and a first transparent substrate. The transparent solar cell includes a first electrode, a photoelectric conversion layer, a second electrode, and a second transparent substrate in sequence.

### CROSS-REFERENCE TO RELATED APPLICATION

This application claims the priority benefit of Taiwan application serial no. 96151543, filed on Dec. 31, 2007. The entirety of the above-mentioned patent application is hereby incorporated by reference herein and made a part of this specification.

### BACKGROUND OF THE INVENTION

1. Field of the Invention

The present invention generally relates to a transparent solar cell module.

2. Description of Related Art

Solar energy is a renewable and environment-friendly energy that attracts the most attention for solving the problems of the shortage and pollution of petrochemical energies. The early solar cell is disposed on the roof. However, in cities with so many people and a limited area, the area of the top floor is limited with a small area for installation. The glass curtain wall of the vertical surface of the building has a large area and is not limited by government regulations. A transparent solar cell can be directly integrated into the glass curtain, thus having a niche market in the application in building, which is a developable area of the transparent solar cell module.

Generally speaking, solar cell integrated into a glass curtain wall of a building must have good light transmittance. In addition to the advantages of energy saving and having beautiful appearance, the transparent solar cell also meets the requirements for humanity living in these applications. Therefore, building integrated photovoltaic (BIPV) undoubtedly is a hot research topic in the current and in the future.

Currently, relevant techniques about transparent thin film solar cells and methods for manufacturing the same have been disclosed in patents.

U.S. Pat. No. 4,795,500 sets forth a photovoltaic device. The photovoltaic device includes a first transparent substrate, a transparent conductive layer, a photoelectric conversion layer, a back electrode, and a photoresist. The photovoltaic device has holes in the back electrode, the photoelectric conversion layer, and the transparent conductive layer for light transmission. The photoresist used in the photolithographic is not required to be removed for generating colorful effects, thus reducing the metallic luster of the back electrode.

U.S. Pat. No. 4,663,495 sets forth a transparent photovoltaic module. Upper and lower electrodes of the transparent photovoltaic module are made of transparent conductive oxide (TCO) to be irradiated on dual surfaces, and the unabsorbed light can be transmitted, thus forming the transparent photovoltaic module.

U.S. Pat. No. 6,858,461 sets forth a partially transparent photovolatic module. In the partially transparent photovolatic module, a portion of the metal electrode and the photoelectric conversion layer is removed by laser scribing to form at least one groove, such that the photovolatic module is partially transmissive.

Other relevant patents, such as U.S. Pat. No. 4,623,601 and 6,180,871, also set forth other solar cells.

Although the current amorphous silicon thin-film transparent solar cells or the transparent dye-sensitized solar cells can obtain electric power, the silicon thin film or the dye absorbs the light in specific wavelength range, thus generating red or yellow color on the film. When being applied on glass curtain, the external wall of the building does not lose beautiful appearance, but the indoor color hue changes, thus resulting in failure to meet the requirements. Therefore, how apply the BIPV in glass curtain without changing the indoor color hue is an important issue in the future.

On the other hand, although see-through type products have a transmittance increased by 10%, but the efficiency is lost by 30%, and thus the cost for generate per watt power is appropriately increased by about 4%. Further, in addition to chemical vapor deposition (CVD), a laser process is further required to be added for the see-through type products, thus increasing the manufacturing cost and generating the problem of the glare, as a result, the see-through type products are not suitable for being watched at a close distance or for a long period of time by eyes.

### SUMMARY OF THE INVENTION

Accordingly, the present invention is directed to a transparent solar cell module capable of alleviating the glare problem.

The present invention is directed to a transparent solar cell module capable of adjusting the indoor color hue.

The present invention is directed to a transparent solar cell module capable of being used as BIPV.

The present invention provides a transparent solar cell module including an optical transparent substrate and a transparent solar cell. The optical transparent substrate includes an optical filter and a first transparent substrate. The optical filter is located on a surface of the first transparent substrate. The transparent solar cell includes a first electrode, a photoelectric conversion layer, a second electrode, and a second transparent substrate in sequence.

In a transparent solar cell module according to an embodiment of the present invention, the second transparent substrate is a light incident substrate and the first transparent substrate is a light reception substrate, and the first transparent substrate is located between the optical filter and the transparent solar cell.

In a transparent solar cell module according to an embodiment of the present invention, the second transparent substrate is a light incident substrate and the first transparent substrate is a light reception substrate, and the optical filter is located between the first transparent substrate and the transparent solar cell.

The transparent solar cell module of the present invention is capable of alleviating the glare problem.

The transparent solar cell module of the present invention is capable of adjusting the indoor color hue.

The transparent solar cell module of the present invention can be used as BIPV.

In order to make the objects and other objects, features and advantages of the present invention clearer and more understandable, the following embodiments are illustrated in detail with reference to the appended drawings.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1 is a schematic cross-sectional view of a transparent solar cell module according to a first embodiment of the present invention.

FIG. 2 is a schematic cross-sectional view of a transparent solar cell module according to a second embodiment of the present invention.

### DESCRIPTION OF THE EMBODIMENTS

Reference will now be made in detail to the present embodiments of the invention, examples of which are illustrated in the accompanying drawings. Wherever possible, the same reference numbers are used in the drawings and the description to refer to the same or like parts.

The transparent solar cell module of the present invention is composed of a transparent solar cell and an optical transparent substrate. The optical transparent substrate has an optical filter disposed therein to solve the problem of indoor color hue change caused by the photoelectric conversion layer of the transparent solar cell module merely absorbing the light in specific wavelength range, so as to achieve the purpose of controlling the chromaticity diagram of Commission International de l'Eclairage (CIE), the color rendering index (Ra), and the color temperature (CT) of the transmission spectrum of the transparent solar cell. Hereinafter, the position relationship of the optical filter in the transparent substrate is illustrated with reference to several embodiments, but the present invention is not limited thereto.

### First Embodiment

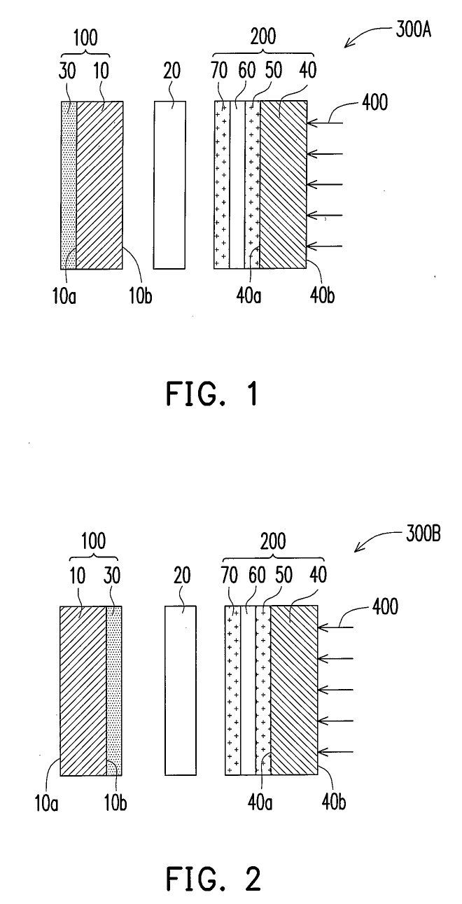

FIG. 1 is a schematic cross-sectional view of a transparent solar cell module according to a first embodiment of the present invention.

Referring to FIG. 1, a transparent solar cell module 300A includes an optical transparent substrate 100 and a transparent solar cell 200, and an insulation layer 20 is sandwiched between the transparent solar cell 200 and the optical transparent substrate 100, the elements shown in the figure are spaced by a certain distance for clarity.

The transparent solar cell 200 includes a transparent substrate 40, and electrode 50, an electrode 70, and a photoelectric conversion layer 60. The electrode 50 of the transparent solar cell 200 is located on a first surface 40a of the transparent substrate 40. The photoelectric conversion layer 60 is sandwiched between the electrode 50 and the electrode 70. The optical transparent substrate 100 includes an optical filter 30 and a transparent substrate 10. The insulation layer 20 is located between a second surface 10b of the transparent substrate 10 and the electrode 70 of the transparent solar cell 200. The optical filter 30 is located on a first surface 10a of the transparent substrate 10.

In an embodiment, transparent substrate 40 serving as a light incident substrate and transparent substrate 10 serving as a light reception substrate, when sunlight 400 is incident to a second surface 40b of the transparent substrate 40, the light of a portion of wavelength range is absorbed at the transparent solar cell 200 for generating electric energy, and the light of another portion of wavelength range passes through the transparent solar cell 200, then passes through the transparent substrate 10 of the optical transparent substrate 100, and finally passes through the optical filter 30. After the light passes through the optical filter 30, the problem of indoor color hue change caused by the photoelectric conversion layer 60 of the transparent solar cell 200 merely absorbing the light in specific wavelength range is alleviated.

A method of manufacturing the transparent solar cell module 300A includes the following steps. First, the transparent solar cell 200 is fabricated on the transparent substrate 40. Next, the optical filter 30 is coated on the first surface 10a of the transparent substrate 10. And then, the transparent solar cell 200 and the transparent substrate 10 with the optical filter 30 coated thereon are packaged by the insulation layer 20.

### Second Embodiment

FIG. 2 is a schematic cross-sectional view of a transparent solar cell module according to a second embodiment of the present invention.

Referring to FIG. 2, a transparent solar cell module 300B includes an optical transparent substrate 100 and a transparent solar cell 200, and an insulation layer 20 is sandwiched between the transparent solar cell 200 and the optical transparent substrate 100, the elements shown in the figure are spaced by a certain distance for clarity.

The transparent solar cell 200 includes a transparent substrate 40, and electrode 50, an electrode 70, and a photoelectric conversion layer 60. The electrode 50 of the transparent solar cell 200 is located on a first surface 40a of the transparent substrate 40. The photoelectric conversion layer 60 is sandwiched between the electrode 50 and the electrode 70. The optical transparent substrate 100 includes an optical filter 30 and a transparent substrate 10. The optical filter 30 is located on a second surface 10b of the transparent substrate 10. The insulation layer 20 is located between the optical filter 30 and the electrode 70 of the transparent solar cell 200.

In an embodiment, transparent substrate 40 serving as a light incident substrate and transparent substrate 10 serving as a light reception substrate, when sunlight 400 is incident to a second surface 40b of the transparent substrate 40, the light of a portion of wavelength range is absorbed at the transparent solar cell 200 for generating electric energy, and the light of another portion of wavelength range passes through the transparent solar cell 200, then passes through the insulation layer 20 and the optical filter 30 of the optical transparent substrate 100, and finally passes through the transparent substrate 10. After the light passes through the optical filter 30, the problem of indoor color hue change caused by the photoelectric conversion layer 60 of the transparent solar cell 200 merely absorbing the light in specific wavelength range is alleviated.

A method of manufacturing the transparent solar cell module 300B includes the following steps. First, the transparent solar cell 200 is fabricated on the transparent substrate 40. Next, the optical filter 30 is coated on the second surface 10b of the transparent substrate 10. And then, the transparent solar cell 200 and the transparent substrate 10 with the optical filter 30 coated thereon are packaged by the insulation layer 20.

The transparent solar cell 200 is, for example, a transparent silicon thin-film solar cell, a transparent dye-sensitized solar cell, or a transparent organic solar cell.

A material of the photoelectric conversion layer 60 is, for example, amorphous silicon, microcrystalline silicon, or an alloy thereof, such as SiGe, a dye, an organic material, or a stacked multilayer structure thereof.

The shape and the structure of the electrode 50, the electrode 70, and the photoelectric conversion layer 60 of the transparent solar cell 200 are not specially limited. The photoelectric conversion layer 60 can have a single junction or dual junctions, or multiple junctions.

The materials of the electrode 50 and the electrode 70 can be the same or different, and can be, for example, transparent conductive oxide (TCO), such as indium tin oxide (ITO), fluorine doped tin oxide (FTO), aluminium doped zinc oxide (AZO), gallium doped zinc oxide (GZO), or a combination thereof.

The transparent substrate 40 can be a rigid substrate or a flexible substrate. The rigid substrate is, for example, a glass substrate serving as a curtain of a building. The flexible substrate is, for example, a plastic substrate.

The transparent substrate 10 can be a rigid substrate or a flexible substrate. The rigid substrate is, for example, a glass substrate serving as a curtain of a building. The flexible substrate is, for example, a plastic substrate. The transparent substrate 10 and the transparent substrate 40 can be the same or different.

A material of the insulation layer 20 is, for example, ethylene vinyl acetate (EVA), polyvinyl butyral (PVB), or another similar material.

The optical filter 30 limits the chromaticity diagram of commission international de l'eclairage (CIE) of the transmission spectrum of the transparent solar cell 200 within a rectangular region formed by CIE (0.10, 0.75) and CIE (0.25, 0.60), and adjusts the color rendering index (Ra) of the transmission spectrum of the transparent solar cell to be greater than 75, and adjusts the color temperature (CT) of the transmission spectrum of the transparent solar cell to 1000-10000 Kelvin degrees. The optical filter 30 is, for example, a stacked film formed by stacking a plurality of high-reflective index film layers having a reflective index n greater than 1.9 and a plurality of low-reflective index film layers having a reflective index n less than 1.9. The high-index layers are, for example, CeO₂, Cr₂O₃, Gd₂O₃, HfO₂, In₂O₃, ITO, La₂O₃, Nb₂O₅, Nd₂O₃, PbO, SnO₂, Ta₂O₅, TiO₂, V₂O₅, WO₃, ZrO₂, ZnO, ZnS, and ZnSe. The low-index layers are, for example, AlF₃, Al₂O₃, BaF₂, BiF₃, CaF₂, CeF₃, GdF₃, LiF, MgF₂, NaF, Na₃AlF₆, Na₅Al₃F₁₄, NdF₃, SiO₂, and Si₂O₃.

The transparent solar cell module of the present invention is capable of alleviating the glare problem, adjusting the indoor color hue, and serving as BIPV, so as to achieve the purpose of being integrated with buildings.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

What is claimed is:

1. A transparent solar cell module, comprising:
an optical transparent substrate, comprising a first transparent substrate and an optical filter, wherein the optical filter is located on a surface of the first transparent substrate; and
a transparent solar cell, comprising a first electrode, a photoelectric conversion layer, a second electrode, and a second transparent substrate in sequence.

2. The transparent solar cell module according to claim 1, wherein the second transparent substrate is a light incident substrate and the first transparent substrate is a light reception substrate.

3. The transparent solar cell module according to claim 2, wherein the first transparent substrate is located between the optical filter and the transparent solar cell.

4. The transparent solar cell module according to claim 3, further comprising an insulation layer located between the transparent solar cell and the first transparent substrate.

5. The transparent solar cell module according to claim 4, wherein a material of the insulation layer comprises ethylene-vinyl acetate (EVA), polyvinyl butyral (PVB).

6. The transparent solar cell module according to claim 2, wherein the optical filter is located between the first transparent substrate and the transparent solar cell.

7. The transparent solar cell module according to claim 6, further comprising an insulation layer located between the optical filter and the transparent solar cell.

8. The transparent solar cell module according to claim 7, wherein a material of the insulation layer comprises ethylene-vinyl acetate (EVA), polyvinyl butyral (PVB).

9. The transparent solar cell module according to claim 1, wherein the optical filter limits a chromaticity diagram of Commission International de l'Eclairage (CIE) of the transmission spectrum of the transparent solar cell within a rectangular region formed by CIE (0.10, 0.75) and CIE (0.25, 0.60).

10. The transparent solar cell module according to claim 1, wherein the optical filter is capable of adjusting the color rendering index (Ra) of the transmission spectrum of the transparent solar cell to be greater than 75.

11. The transparent solar cell module according to claim 1, wherein the optical filter is capable of adjusting the color temperature (CT) of the transmission spectrum of the transparent solar cell to 1000-10000 Kelvin degrees.

12. The transparent solar cell module according to claim 1, wherein the optical filter is a stacked film formed by stacking a plurality of high-reflective index film layers having a reflective index n greater than 1.9 and a plurality of low-reflective index film layers having a reflective index n less than 1.9.

13. The transparent solar cell module according to claim 1, wherein the first transparent substrate is a rigid substrate or a flexible substrate.

14. The transparent solar cell module according to claim 13, wherein the rigid substrate comprises a glass substrate.

15. The transparent solar cell module according to claim 14, wherein the glass substrate is a curtain of a building.

16. The transparent solar cell module according to claim 13, wherein the flexible substrate comprises a plastic substrate.

17. The transparent solar cell module according to claim 1, wherein the transparent solar cell is a transparent thin-film silicon solar cell, a transparent dye-sensitized solar cell, or a transparent organic solar cell.
